(19) United States
(12) Patent Application Publication
(10) Pub. No.: US 2020/0312659 A1
(43) Pub. Date: Oct. 1, 2020

(54) METHOD FOR THE PREPARATION OF GALLIUM OXIDE/COPPER GALLIUM OXIDE HETEROJUNCTION

(71) Applicant: Dalian University of Technology, Dalian City (CN)

(72) Inventors: Hongwei LIANG, Dalian City (CN); Xiaochuan XIA, Dalian City (CN); Heqiu ZHANG, Dalian City (CN)

(21) Appl. No.: 16/614,128

(22) PCT Filed: Dec. 19, 2018
(86) PCT No.: PCT/CN2018/121989

§ 371 Date: Nov. 15, 2019

(51) Int. Cl. H01L 21/02; C30B 29/22; C30B 25/18; C30B 33/10

(52) U.S. Cl. CPC H01L 21/02565; H01L 21/02658; C30B 33/10; C30B 29/22; C30B 25/18; H01L 21/02664

(57) ABSTRACT

The present invention belongs to the field of semiconductor materials preparation technology, and relates to a preparation method of gallium oxide/copper gallium oxide heterojunction. In this method, the gallium oxide is pre-treated before the copper source is deposited on the pre-treated gallium oxide, or directly cover the copper source layer on the pretreated gallium oxide. Then, the gallium oxide with copper source is placed in a high temperature furnace in proper form and then heat treated for a certain time under certain conditions, so that the copper atomics can be controlled to diffuse into gallium oxide to form corresponding copper-gallium-oxygen alloys. Further the copper-gallium-oxygen alloys forms gallium oxide/copper gallium oxide heterojunction having good interfacial properties with gallium oxide which does not undergo copper diffusion. The advantage is that the high quality copper gallium oxide material can be prepared. The required equipment and process are simple and controllable.

The present invention belongs to the field of semiconductor materials preparation technology, and specifically relates to a preparation method of gallium oxide/copper gallium oxide heterojunction.

### BACKGROUND

The wide band gap semiconductor materials represented by gallium oxide related materials have many outstanding advantages, such as wide band gap, high breakdown electric field, corrosion resistance and radiation resistance. It has important applications in the fabrication of high-efficiency ultraviolet detectors, gas sensors, friendly biosensors, and high-frequency, high-power, rad-hard and other electronic devices. Copper gallium oxide compounds have excellent properties and broad application prospects. At present, little research has been done on the preparation of gallium oxide/copper gallium oxide heterojunction. The common methods used for preparing copper gallium oxide are mainly chemical synthesis and physical vapor deposition, such as sol-gel, laser pulse deposition or magnetron sputtering. Most of the copper gallium oxide films prepared by the above methods are amorphous or polycrystalline, and their crystalline quality is not high enough, resulting in poor material and interface properties between gallium oxide and copper gallium oxide structure, which shows poor heterojunction characteristics. It greatly limits the applications of this heterojunction in detectors, power devices, optoelectronic devices and sensors field.

### SUMMARY

The object of the present invention is to provide a method for the preparation of gallium oxide copper gallium oxide heterojunction, in view of the above-mentioned problem of the preparation of a high quality copper gallium oxide thin film which is effective and has good process compatibility. In the method, the gallium oxide material is pre-treated before an appropriate amount of copper source is pre-deposited or covered on the surface of the gallium oxide single crystal or film. Then, the gallium oxide with copper source is placed in a high temperature furnace in proper form and then heat treated for a certain time under certain conditions, so that the copper atomics can be controlled to diffuse into gallium oxide to form corresponding copper-gallium-oxygen alloys. Further the copper-gallium-oxygen alloys forms gallium oxide/copper gallium oxide heterojunction having good interfacial properties with gallium oxide which does not undergo copper diffusion.

### The Technical Solution of the Invention

A method for preparing gallium oxide/copper gallium oxide heterojunction, the steps are as follows:

Step 1: Put the gallium oxide materials in corrosive liquid for 5 min-5 h to obtain ideal surface;

Step 2: Put gallium oxide materials in quartz boat or quartz tube and put into furnace, the temperature of the furnace is 700° C.˜1100° C., the pressure is 1×10⁻⁴ Pa˜1×10⁵ Pa, the gas atmosphere is a reducing gas or inert gas, the heating time is 1 min to 120 min; take out gallium oxide material after temperature down to room temperature;

Step 3: Pre-deposit the copper source on gallium oxide material, or directly cover the copper source layer on the gallium oxide material; the thickness of copper source layer is between 10 nm and 10 microns;

Step 4: Put gallium oxide materials that treated after step 3 in quartz boat or quartz tube and put into furnace, the temperature of the furnace is 700° C.˜1300° C., the pressure is 1×10⁻³ Pa˜1×10⁶ Pa, the gas atmosphere is a reducing gas, air, water vapor or nitrogen, the heating time is 1 min to 50 min; take out after temperature down to room temperature;

Step 5: Subsequent processing of copper gallium oxide: use a cleaning fluid to get rid of the residue on the surface of copper gallium oxide. Use the deionized water to produce secondary cleaning. Then, dry the sample and properly kept it. The copper gallium oxide thin films include CuGa₂O₄ or CuGaO₂ alloy, and copper doping.

The gallium oxide material is single crystal, polycrystalline, and the epitaxial film on the substrate.

The copper source is elemental copper or copper oxide.

### Beneficial Effect of the Invention

The outstanding advantage of the invention is that the high quality copper gallium oxide material can be prepared. The required equipment and process are simple and controllable. It can form ideal interface and obtain ideal junction characteristics. The copper diffusion technology of this invention can be used for integrated manufacturing of various kinds of devices, and then a new type of copper gallium oxide device is developed.

### DESCRIPTION OF THE DRAWINGS

FIG. 1 is a schematic diagram of the gallium oxide single crystal with copper pre-deposited layer.

FIG. 2 is a schematic diagram of the gallium oxide/copper gallium oxide heterojunction based on gallium oxide single crystal.

FIG. 3 is the X-ray diffraction result of the gallium oxide/copper gallium oxide structure

FIG. 4 is a schematic diagram of the gallium oxide film with copper pre-deposited layer

FIG. 5 is a schematic diagram of the gallium oxide/copper gallium oxide heterojunction based on gallium oxide film.

### DETAILED DESCRIPTION

The specific embodiments of the present invention are further described below in conjunction with the accompanying drawings and technical solutions.

### Example 1

The present embodiment provides a method for preparing gallium oxide/copper gallium oxide heterojunction, including the following process steps:

Step 1: The thickness of the gallium oxide crystal is 600 microns. Its surface is a square with a length of 5 mm. The copper source is high purity copper metal. Put the gallium oxide crystal in corrosive liquid for 5 h.

Step 2: Put gallium oxide materials in quartz boat or quartz tube, the temperature is 900° C., the pressure is 0.1 Pa, the gas atmosphere is air, the heating time is 60 min, take out after temperature down to room temperature.

Step 3: The copper film (1 microns) is pre-deposited on the acid-treated gallium oxide single crystal by thermal annealing as shown in FIG. 1.

Step 4: Put gallium oxide materials that treated after step 3 in tube furnace with single temperature zone, the temperature is 1200° C., the gas atmosphere is an air, the heating time is 50 min;

Step 5: Take out after temperature down to room temperature;

Step 6: Use hydrochloric acid to get rid of the residue on the surface of copper gallium oxide.

Step 7: Use the deionized water to produce secondary cleaning for the residue produced in step 6.

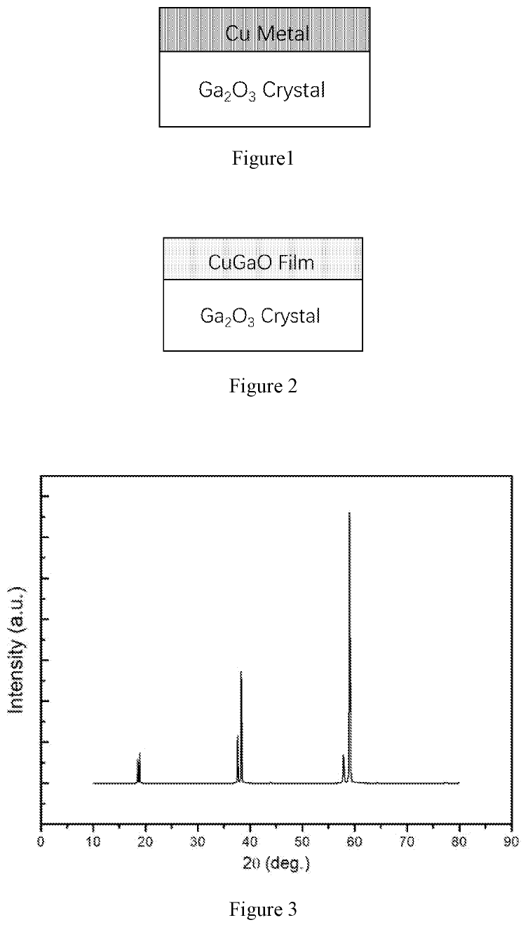

Step 8: Dry the gallium oxide material to form gallium oxide/copper gallium oxide heterojunction as shown in FIG. 2.

It has been detected that a gallium oxide/copper gallium oxide heterojunction has been formed in this embodiment. FIG. 3 shows the X-ray diffraction spectra of gallium oxide/copper gallium oxide heterojunction. Using the technology of the invention, the prepared copper-gallium-oxygen material has single orientation, high crystal quality and good structural characteristics of the heterojunction.

### Example 2

This embodiment provides a preparation method of gallium oxide/copper gallium oxide heterojunction, including the following process steps:

Step 1: Gallium oxide thin films with thickness of 1 micron and surface of 10 mm square are prepared on sapphire substrates by MOCVD method. The selected copper source is high purity copper. Gallium oxide single crystal is placed in acid etching solution for 5 minutes.

Step 2: Put gallium oxide materials in quartz boat or quartz tube, the temperature is 850° C., the pressure is 100 Pa, the gas atmosphere is hydrogen, the heating time is 5 min, take out after temperature down to room temperature.

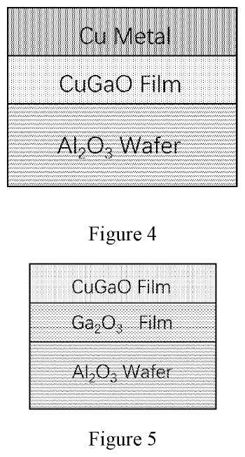

Step 3: Pre-deposit a 100 nm thick copper layer on the gallium oxide thin film by thermal evaporation method, as shown in FIG. 4.

Step 4: Put the sample processed in step 3 into the quartz tube, control the vacuum in the quartz tube to be 1×10⁻³ Pa, and seal the quartz tube.

Step 5: The closed quartz tube placed in step 4 is put into a single temperature zone tube furnace for heat treatment, and the treatment temperature is 900° C. and the treatment time is 50 min;

Step 6: After the temperature drops to room temperature, take out the sample.

Step 7: Use dilute hydrochloric acid to firstly clean the residue on the surface of gallium oxide material once.

Step 8: Deionized water is used for the secondary cleaning of the residues produced in step 7 twice.

Step 9: The sample is dried to form gallium oxide/copper gallium oxide heterojunction as shown in FIG. 5.

It has been detected that a copper gallium oxide material has been formed in this embodiment.

Finally, it should be noted that the above embodiments are used only to illustrate the technical scheme of the present invention, not to limit it; although the present invention is described in detail with reference to the above embodiments, ordinary technicians in the field should understand that they can still modify the technical scheme recorded in the aforementioned embodiments, or carry out some or all of their technical features, etc. Same substitution; and these modifications or substitutions do not detach the essence of the corresponding technical scheme from the scope of the technical scheme according to the embodiments of the present invention.

1. A method for the preparation of gallium oxide/copper gallium oxide heterojunction, wherein the steps are as follows:
step 1: put the gallium oxide materials in corrosive liquid for 5 min-5 h to obtain ideal surface;
step 2: put gallium oxide materials in quartz boat or quartz tube, the temperature is 700° C.˜1100° C., the pressure is 1×10⁻⁴ Pa˜1×10⁵ Pa, the gas atmosphere is a reducing gas or inert gas, the heating time is 1 min to 120 min; take out after temperature down to room temperature;
step 3: pre-deposit the copper source on gallium oxide material, or directly cover the copper source layer on the gallium oxide material; the thickness of copper layer source is between 10 nm and 10 microns;
step 4: put gallium oxide materials that treated after step 3 in quartz boat or quartz tube, the temperature is 700° C.˜1300° C., the pressure is 1×10⁻³ Pa˜1×10⁶ Pa, the gas atmosphere is a reducing gas, air, water vapor or nitrogen, the heating time is 1 min to 50 min; take out after temperature down to room temperature;
step 5: subsequent processing of copper gallium oxide: use a cleaning fluid to get rid of the residue on the surface of copper gallium oxide; use the deionized water to produce secondary cleaning for the produced residue; dry the sample and properly kept it, that is copper gallium oxide thin films which comprise CuGa₂O₄ or CuGaO₂ alloy as well as copper doping.

2. The method for the preparation of copper gallium oxide thin film according to claim 1, wherein the gallium oxide material is single crystal, polycrystalline, and the epitaxial film on the substrate.

3. The method for the preparation of copper gallium oxide thin film according to the claim 1, the copper source is elemental copper or copper oxide.
